(19) United States
(12) Patent Application Publication
(10) Pub. No.: US 2011/0041766 A1
(43) Pub. Date: Feb. 24, 2011

(54) PLASMA SOURCE

(75) Inventors: Shih-Cheng Tseng, Taoyuan County (TW); Cheng-Chang Hsieh, Chiayi City (TW); Ming-Chung Yang, Taoyuan County (TW); Der-Jun Jan, Taoyuan County (TW); Chi-Fong Ai, Taoyuan County (TW)

Correspondence Address: WPAT, PC;INTELLECTUAL PROPERTY ATTORNEYS, 7225 BEVERLY ST., ANNANDALE, VA, 22003, US

(73) Assignee: Institute of Nuclear Energy Research Atomic Energy Council, Executive Yuan, Taoyuan County (TW)

(21) Appl. No.: 12/732,753

(22) Filed: Mar. 26, 2010

(30) Foreign Application Priority Data
Aug. 21, 2009 (TW) 098128149

(51) Int. Cl. C23C 16/513

(52) U.S. Cl. 118/723 E

(57) ABSTRACT

A plasma source comprises a vacuum chamber, a plurality of discharge tubes, a plurality of permanent magnets, a plurality of RF antennas, and an RF power distribution circuit. The RF power distribution circuit is electrically coupled to an RF power supply and each of the plurality of RF antennas. The lengths of the transmission paths between each of the plurality of RF antennas and the RF power supply are the same, so that the RF power supply can provide each of discharge tubes with the same RF power.

### FIELD OF THE INVENTION

The present invention generally relates to a plasma source and, more particularly, to a helicon plasma source with permanent magnets that uses a radio frequency (RF) power distribution circuit so that an RF power supply is capable of providing each of a plurality of discharge tubes with the same RF power.

### BACKGROUND OF THE INVENTION

In the industry, the plasma source has been widely used in many film formation processes such as plasma enhanced chemical vapor deposition (PECVD) for making solar cells, semiconductor devices, flat-panel displays, and the like. Large-area PECVD does not only lower the manufacturing cost, but also saves time. It has thus become a key topic in the plasma technology to develop large-area PECVD processing.

U.S. Pat. Pub. No. 2008/0246406 A1 discloses a helicon plasma source 10 with permanent magnets, as shown FIG. 1. The plasma source comprises: a vacuum chamber 11, a discharge tube 12, at least a permanent magnet 13, an RF antenna 14, a gas inlet 15 and an RF power supply 16. The gas inlet 15 is coupled to a gas source (not shown) so as to provide the discharge tube 12 with a gaseous source to generate plasma. The RF power supply 16 is electrically coupled to the RF antenna 14 to provide RF power.

To implement large-area PECVD processing, as shown in FIG. 2A, the plasma source 10a comprises a plurality of discharge portions 12′ (for example, 8 discharge portions in FIG. 2A) and an RF power distribution circuit 17a. Each discharge portion 12′ is provided with a discharge tube 12, at least a permanent magnet 13, an RF frequency antenna 14 and a gas inlet 15. The RF antenna 14 is electrically coupled to a branch circuit of the RF power distribution circuit 17a through a connecting wire 18.

However, in the plasma source 10a, the lengths of transmission paths from the RF power supply 16 through the RF power distribution circuit 17a to the respective RF antennas 14 are different, which leads to different impedances that cause the RF power supply to provide the discharge tubes 12 with different RF power ratings. Accordingly, the plasma densities in the discharge tubes 12 are different, especially in low-pressure or low-power (high-impedance) processing, which results in non-uniform deposition.

Therefore, there is need in providing a plasma source with permanent magnets, capable providing each of a plurality of discharge tubes with the same RF power so as to achieve identical plasma density in each discharge tube.

### SUMMARY OF THE INVENTION

It is one object of the present invention to provide a plasma source with permanent magnets, capable providing each of a plurality of discharge tubes with the same RF power so as to achieve identical plasma density in each discharge tube.

It is another object of the present invention to provide a plasma source, using an RF power distribution circuit so thay an RF power supply provides each of a plurality of discharge tubes with the same RF power to achieve the same plasma density in each discharge tube.

In order to achieve the foregoing objects, the present invention provides a plasma source, comprising: a vacuum chamber; a plurality of discharge portions, each comprising a discharge tube, at least a permanent magnet and an RF antenna, and each discharge tube being channeled with the vacuum chamber; and an RF power distribution circuit, electrically coupled to the plurality of discharge portions for distributing RF power to the plurality of discharge portions, the RF power distribution circuit further comprising a plurality of branches, wherein each branch comprises at least a branch circuit and the branches of the same order comprise the same number of branch circuits, wherein the branch circuits of the same branch have the same length of transmission paths, wherein each branch circuit of a last branch is electrically coupled to an RF antenna of one of the discharge portions so that the discharge portions have the same impedance.

### BRIEF DESCRIPTION OF THE DRAWINGS

The objects and spirits of the embodiments of the present invention will be readily understood by the accompanying drawings and detailed descriptions, wherein:

FIG. 1 is a cross-sectional view of a prior art plasma source with a single discharge tube;

FIG. 2A is a top view of a prior art plasma source with a plurality of discharge tubes; and

FIG. 2B is a top view of a plasma source with a plurality of discharge tubes according to a first embodiment of the present invention.

### DETAILED DESCRIPTION OF THE PREFERRED EMBODIMENT

The present invention can be exemplified but not limited by various embodiments as described hereinafter.

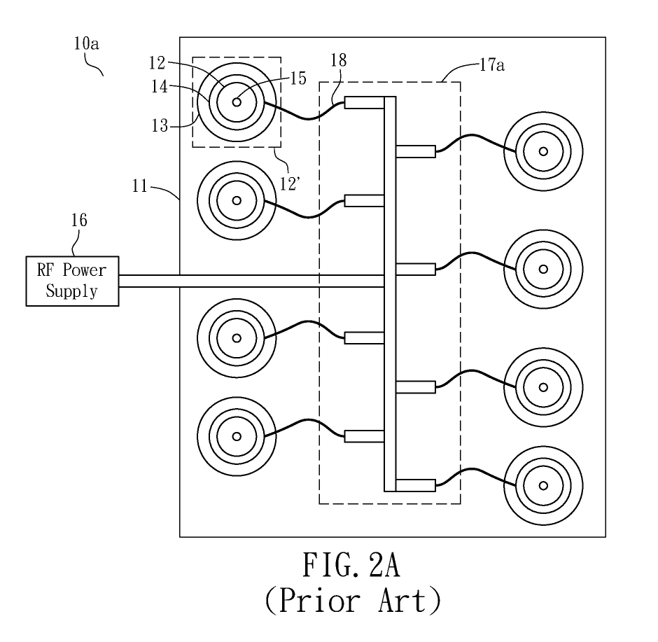

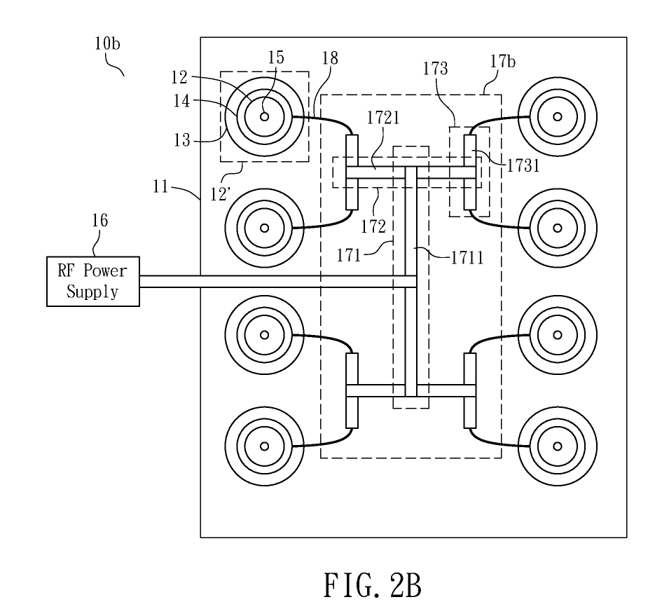

Please refer to FIG. 2B, which is a top view of a plasma source with a plurality of discharge tubes according to a first embodiment of the present invention. The plasma source 10b comprises: a vacuum chamber 11, a plurality of discharge tubes 12, a plurality of permanent magnets 13, a plurality of RF antennas 14, a plurality of gas inlets 15, an RF power supply 16 and an RF power distribution circuit 17b.

In the present embodiment, each discharge tube 12 is channeled with the vacuum chamber 11. The plurality of gas inlets 15 are coupled to a gaseous source (not shown) to providing the plurality of discharge tubes 12 with gas to generate plasma.

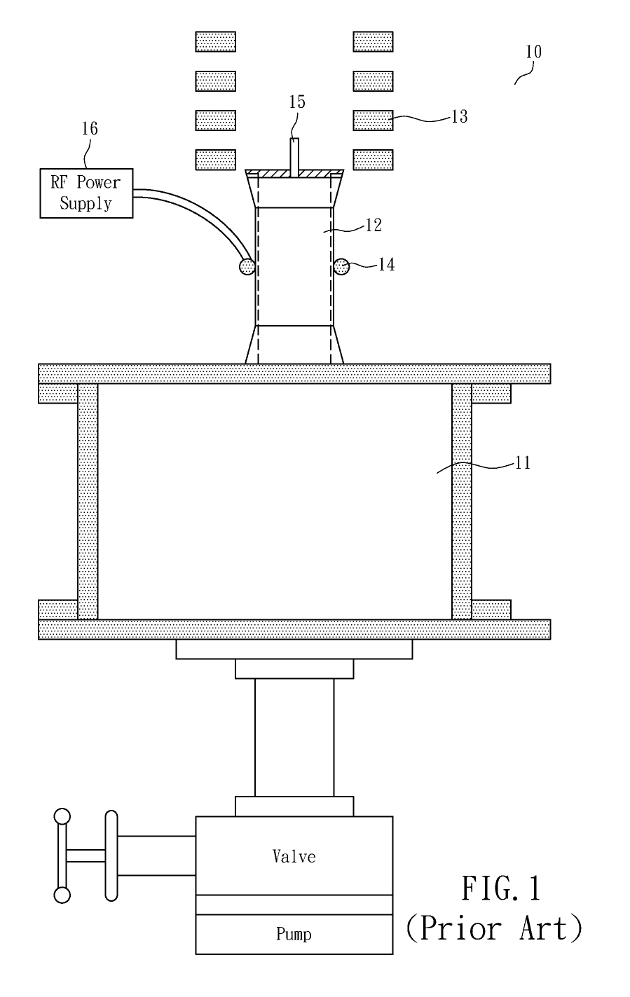

In the present embodiment, a plurality of discharge portions 12′ are constructed by the plurality of discharge tubes 12, the plurality of permanent magnets 13 and the plurality of RF antennas 14. Each discharge portion 12′ comprises a discharge tube 12, at least a permanent magnet 13 and an RF antenna 14. The number of discharge tubes 12, the number of RF antennas 14 and the number of discharge portions 12′ are identical. In the present embodiment, the plasma source 10b is only provided with 8 discharge tubes in only 8 discharge portions 12′. The discharge tube 12, the permanent magnet 13 and the RF antenna 14 in each discharge portion 12′ are disposed in the same way as the prior art in FIG. 1.

In the present embodiment, the RF power distribution circuit 17b is electrically coupled to the RF power supply 16 to distribute RF power to the 8 discharge portions 12′. The RF power distribution circuit 17b comprises three orders of branches, namely: a first-order branch 171, two second-order branches 172 and four third-order branches 173. The first-order branch 171 comprises two first-order branch circuits 1711. Each second-order branch 172 comprises two second-order branch circuits 1721. Each third-order branch 173 comprises two third-order branch circuits 1731. Each branch circuit of the same branch is made of the same material. Each branch circuit of the same branch is the same in width, in length and in impedance and has the same inner structure. Each third-order branch circuit 1731 of the third-order branches 173 is electrically coupled to an RF antenna 14 of a discharge portion 12′ through a connecting wire 18 with the same impedance.

When the plasma source 10b of the present invention is a water-cool helicon plasma source with permanent magnets, the branch circuits 1711, 1721 and 1731 can be hollowed transmission lines made of copper. For example, the branch circuits 1711, 1721 and 1731 can be hollowed copper tubes.

Since the plasma source 10b of the present invention uses the RF power distribution circuit 17b, the transmission path between the RF power supply 16 and each RF antenna 14 exhibits the same impedance. Therefore, the RF power supply 16 provides each discharge tube 12 with the same RF power to generate plasma with the same density in each discharge tube 12.

Even though the embodiment of the present invention is exemplified by the plasma source with 8 discharge tubes, the present invention is not limited to the number of discharge tubes, and the number of orders of branches. The present invention is not limited to the number of branch circuits in the same branch.

The present invention discloses a plasma source with permanent magnets that uses a radio frequency (RF) power distribution circuit so that an RF power supply is capable of providing each of a plurality of discharge tubes with the same RF power. Therefore, the present invention is useful, novel and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A plasma source, comprising:
a vacuum chamber;
a plurality of discharge portions, each comprising a discharge tube, at least a permanent magnet and an RF antenna, and each discharge tube being channeled with the vacuum chamber; and
an RF power distribution circuit, electrically coupled to the plurality of discharge portions for distributing RF power to the plurality of discharge portions, the RF power distribution circuit further comprising:
a plurality of branches,
wherein each branch comprises at least a branch circuit and the branches of the same order comprise the same number of branch circuits,
wherein the branch circuits of the same branch have the same length of transmission paths,
wherein each branch circuit of a last branch is electrically coupled to an RF antenna of one of the discharge portions so that the discharge portions have the same impedance.

2. The plasma source as recited in claim 1, further comprising an RF power supply electrically coupled to the RF power distribution circuit for providing RF power.

3. The plasma source as recited in claim 1, wherein each branch circuit of the same branch is made of the same material.

4. The plasma source as recited in claim 3, wherein each branch circuit of the same branch is the same in width.

5. The plasma source as recited in claim 3, wherein each branch circuit of the same branch has the same inner structure.

6. The plasma source as recited in claim 3, wherein each branch circuit of the same branch is the same in length and in impedance.

7. The plasma source as recited in claim 3, wherein each branch circuit has a hollowed inner structure.

8. The plasma source as recited in claim 3, wherein each branch circuit is a hollowed copper tube.
